(19) United States
(12) Patent Application Publication
(10) Pub. No.: US 2007/0284139 A1
(43) Pub. Date: Dec. 13, 2007

(54) SAWN INTEGRATED CIRCUIT PACKAGE SYSTEM

(76) Inventors: Chee Keong Chin, Shanghai (CN); Yu Feng Feng, Shanghai (CN); Dan Feng Zhu, Shanghai (CN); Feng Yao, Shanghai (CN)

Correspondence Address: ISHIMARU & ZAHRT LLP, 333 W. EL CAMINO REAL, SUITE 330, SUNNYVALE, CA, 94087, US

(21) Appl. No.: 11/761,195

(22) Filed: Jun. 11, 2007

Related U.S. Application Data
(60) Provisional application No. 60/804,429, filed on Jun. 10, 2006.

(51) Int. Cl. H05K 1/16; H01L 23/02

(52) U.S. Cl. 174/260; 257/686

(57) ABSTRACT

An integrated circuit package system is provided including providing an integrated circuit die, forming an encapsulation over the integrated circuit die, and sawing the encapsulation with a multi-level saw.

### CROSS-REFERENCES TO RELATED APPLICATION

This application claims the benefit of U.S. Provisional Patent Application No. 60/804,429 filed Jun. 10, 2006.

### TECHNICAL FIELD

The present invention relates generally to an integrated circuit package system, and more particularly to an integrated circuit package system with an encapsulation.

### BACKGROUND ART

Electronics demand more integrated circuits in an integrated circuit package while paradoxically providing less physical space in the system for the increased integrated circuits content. Some technologies primarily focus on integrating more functions into each integrated circuit. Other technologies focus on stacking these integrated circuits into a single package. While these approaches provide more functions within an integrated circuit, they do not fully address the requirements for lower height, smaller space, and cost reduction.

Modern electronics, such as smart phones, personal digital assistants, location based services devices, servers, and storage arrays, are packing more integrated circuits into an ever shrinking physical space with expectations for decreasing cost. Numerous technologies have been developed to meet these requirements. Some of the research and development strategies focus on new technologies while others focus on improving the existing technologies.

One approach to pack more integrated circuits into a single package, have the integrated circuits take up less space, or formed in a profile to fit into mating portions in electronic systems is to create contoured or sides of the integrated circuits or its package that is not strictly vertical. For example, sides of integrated circuits or integrated circuit packages may have stepped or angled configurations.

Conventional approaches to form the non-vertical sides require two types of saws and multiple sawing steps reducing the overall manufacturing throughput or units per hour (UPH). The multiple sawing steps increase the wear of the saw blades and decrease the lifetime of the saw blades. Also, cutting the integrated circuits or integrated circuit packages multiple times with different saw blades might cause damage at or near the interface of the different cuts. For example, the interface near the different cuts are more prone to chipping, cracking, and tearing leading to reduced yield, reduced reliability, and increased cost.

Thus, a need still remains for an integrated circuit package system providing low cost manufacturing, improved yield, improved reliability, and improved throughput. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system including providing an integrated circuit die, forming an encapsulation over the integrated circuit die, and sawing the encapsulation with a multi-level saw.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a bottom view of an integrated circuit package system in a first embodiment of the present invention;

FIG. 2 is a cross-sectional view of the integrated circuit package system along line 2-2 of FIG. 1;

FIG. 3 is a cross-sectional view of an integrated circuit package system exemplified by the bottom view of FIG. 1 in a second embodiment of the present invention;

FIG. 4 is a top view of an integrated circuit package system in a third embodiment of the present invention;

FIG. 5 is a cross-sectional view of the integrated circuit package system along line 5-5 of FIG. 4;

FIG. 6 is a bottom view of an integrated circuit package system in a fourth embodiment of the present invention;

FIG. 7 is a cross-sectional view of the integrated circuit package system along line 7-7 of FIG. 6;

FIG. 8 is a perspective view of a wafer in a molding phase in accordance with an embodiment of the present invention;

FIG. 9 is a cross-sectional view of the wafer along line 9-9 of FIG. 8;

FIG. 10 is the structure of FIG. 9 in a thinning phase;

FIG. 11 is a portion of the structure FIG. 10 in a singulating phase along a parallel direction to 9-9 of FIG. 8;

FIG. 12 is a portion of the structure FIG. 10 in the singulating phase along line 9-9 of FIG. 8;

FIG. 13 is a top view of a carrier frame in accordance with an embodiment of the present invention;

FIG. 14 is a cross-sectional view of the carrier frame in a singulating phase along line 14-14 of FIG. 13;

FIG. 15 is a more detailed cross-sectional view of the structure of FIG. 14;

FIG. 16 is the structure of FIG. 15 post singulation;

FIG. 17 is a cross-sectional view of a portion the integrated circuit package system of FIG. 7 in a singulating phase; and

FIG. 18 is a flow chart of an integrated package system for manufacturing the integrated circuit package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGS.

In addition, where multiple embodiments are disclosed and described having some features in common, for clarity and ease of illustration, description, and comprehension thereof, similar and like features one to another will ordinarily be described with like reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “processing” as used herein includes deposition of material, patterning, exposure, development, etching, cleaning, molding, and/or removal of the material or as required in forming a described structure. The term “system” as used herein means and refers to the method and to the apparatus of the present invention in accordance with the context in which the term is used.

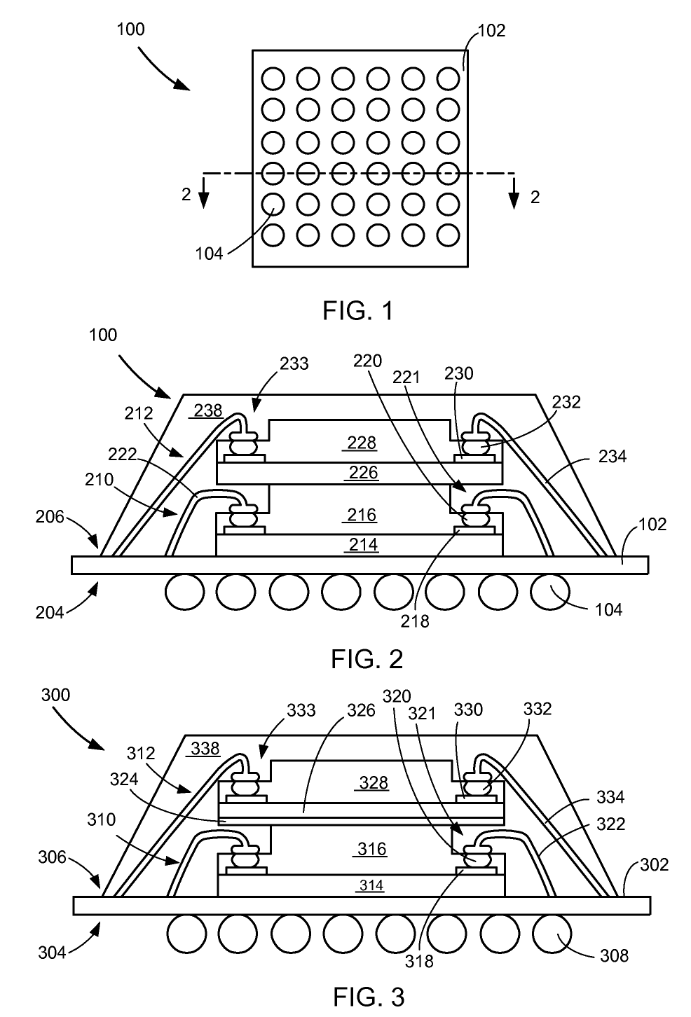

Referring now to FIG. 1, therein is shown a bottom view of an integrated circuit package system 100 in a first embodiment of the present invention. The bottom view depicts a carrier 102, such as printed circuit board or a laminate substrate, with external interconnects 104, such as conductive balls or conductive bumps comprised of solder or other metal or metal alloys. For illustrative purposes, the external interconnects 104 are shown distributed across the carrier 102 in an array configuration, although it is understood that the external interconnects 104 may be distributed differently. For example, predetermined locations may be depopulated and may not have the external interconnects 104 or the external interconnects 104 may be across the carrier 102 in a peripheral configuration.

Also for illustrative purposes the carrier 102 and the external interconnects 104 are shown as formed from a single structure, although it is understood that the carrier 102 and the external interconnects 104 may be formed from a single structure. For example, the carrier 102 and the external interconnects 104 may be formed from a lead frame (not shown) such that the carrier 102 may include a paddle (not shown), such as a die-attach paddle, and the external interconnects 104 may be formed as leads (not shown) or terminal pads (not shown).

Referring now to FIG. 2, therein is shown a cross-sectional view of the integrated circuit package system along line 2-2 of FIG. 1. The carrier 102 includes a first surface 204 and a second surface 206 opposite to the first surface 204. The external interconnects 104 are preferably attached to the first surface 204. A first integrated circuit structure 210 is preferably mounted over the second surface 206 of the carrier 102. A second integrated circuit structure 212 is preferably stacked over the first integrated circuit structure 210.

The first integrated circuit structure 210 preferably includes a first integrated circuit die 214 having a first insulating structure 216, such as an epoxy molding compound. The first integrated circuit die 214 has first bond pads 218 electrically connected to the integrated circuits (not shown) within the first integrated circuit die 214. The first insulating structure 216 preferably surrounds first conductive interconnects 220, such as solder bumps or gold bumps, bonded to the first bond pads 218. The first insulating structure 216 has a first recess 221 formed into the edges of the first insulating structure 216.

For illustrative purposes, the first integrated circuit structure 210 is shown with a structure having the first insulating structure 216 exposing a side of the first integrated circuit die 214 opposite the first insulating structure 216, although it is understood that the first insulating structure 216 may not expose the other side of the first integrated circuit die 214. For example, the first integrated circuit structure 210 may be formed in as packaged integrated circuit.

The first insulating structure 216 at the first recess 221 partially exposes the first conductive interconnects 220. First interconnects 222, such as bond wires or ribbon bond wires, couple the first conductive interconnects 220 to the carrier 102. The height of the first recess 221 provides a predetermined clearance for the first interconnects 222 disposed underneath the second integrated circuit structure 212. The combined height of the first insulating structure 216 and the first integrated circuit die 214 is greater than the height of the first interconnects 222.

For illustrative purposes, the first integrated circuit structure 210 is shown with the first conductive interconnects 220 coupled with the first bond pads 218, although it is understood that the first integrated circuit structure 210 may not include the first conductive interconnects 220. For example, the first integrated circuit structure 210 may have the first recess 221 of the first insulating structure 216 expose the first bond pads 218 and the first interconnects 222 attached with the first bond pads 218.

The second integrated circuit structure 212 preferably includes a second integrated circuit die 226 having a second insulating structure 228, such as an epoxy molding compound. A bottom surface of the second integrated circuit die 226 is preferably coupled to a top surface of the first insulating structure 216 of the first integrated circuit structure 210. The second integrated circuit die 226 has preferably second bond pads 230 electrically connected to the integrated circuits (not shown) within the second integrated circuit die 226.

For illustrative purposes, the second integrated circuit structure 212 is shown with a structure having the second insulating structure 228 exposing a side of the second integrated circuit die 226 opposite the second insulating structure 228, although it is understood that the second insulating structure 228 may not expose the other side of the second integrated circuit die 226. For example, the second integrated circuit structure 212 may be formed in as packaged integrated circuit.

The second insulating structure 228 preferably includes second conductive interconnects 232, such as solder bumps or gold bumps, bonded to the second bond pads 230, and a second recess 233 formed into the edges of the second insulating structure 228. The second insulating structure 228 at the second recess 233 preferably partially exposes the second conductive interconnects 232. Second interconnects 234, such as bond wires or ribbon bond wires, preferably couple the second conductive interconnects 232 to the carrier 102.

For illustrative purposes, the second integrated circuit structure 212 is shown with the second conductive interconnects 232 coupled with the second bond pads 230, although it is understood that the second integrated circuit structure 212 may not include the second conductive interconnects 232. For example, the second integrated circuit structure 212 may have the second recess 233 of the second insulating structure 228 expose the second bond pads 230 and the second interconnects 234 attached with the second bond pads 230.

The first recess 221 and the second recess 233 may be preferably formed along multiple sides of the first integrated circuit structure 210 and the second integrated circuit structure 212. The first integrated circuit structure 210 and the second integrated circuit structure 212 may preferably be encapsulated in an encapsulation 238, such as an epoxy molding compound, covering the first interconnects 222 and the second interconnects 234 and forming the integrated circuit package system 100 with a low profile.

For illustrative purposes, the integrated circuit package system 100 is shown having the second integrated circuit structure 212 stacked over the first integrated circuit structure 210, although it is understood that the integrated circuit package system 100 may not have the same number of integrated circuit structures, such as the first integrated circuit structure 210 and the second integrated circuit structure 212. For example, the integrated circuit package system 100 may have the first integrated circuit structure 210 without stacking the second integrated circuit structure 212 thereover. Also, as another example, the integrated circuit package system 100 may have more than the first integrated circuit structure 210 and the second integrated circuit structure 212.

Referring now to FIG. 3, therein is shown a cross-sectional view of an integrated circuit package system 300 exemplified by the bottom view of FIG. 2 in a second embodiment of the present invention. The integrated circuit package system 300 includes a similar structure to the integrated circuit package system 100 of FIG. 2.

A carrier 302, such as a printed circuit board or a laminate substrate, includes a first surface 304 and a second surface 306 opposite to the first surface 304. External interconnects 308, such as conductive balls or conductive bumps comprised of solder or other metal or metal alloys, are preferably attached to the first surface 304. A first integrated circuit structure 310 is preferably mounted over the second surface 306 of the carrier 302. A second integrated circuit structure 312 is preferably stacked over the first integrated circuit structure 310.

The first integrated circuit structure 310 preferably includes a first integrated circuit die 314 having a first insulating structure 316, such as an epoxy molding compound. The first integrated circuit die 314 has first bond pads 318 electrically connected to the integrated circuits (not shown) within the first integrated circuit die 314. The first insulating structure 316 preferably surrounds first conductive interconnects 320, such as solder bumps or gold bumps, bonded to the first bond pads 318. The first insulating structure 316 has a first recess 321 formed into the edges of the first insulating structure 316.

The first insulating structure 316 at the first recess 321 partially exposes the first conductive interconnects 320. First interconnects 322, such as bond wires or ribbon bond wires, couple the first conductive interconnects 320 to the carrier 302. The height of the first recess 321 provides a predetermined clearance for the first interconnects 322 disposed underneath the second integrated circuit structure 312. The combined height of the first insulating structure 316 and the first integrated circuit die 314 is greater than the height of the first interconnects 322.

A film 324 is preferably applied between the top surface of the first insulating structure 316 of the first integrated circuit structure 310 and the bottom surface of a second integrated circuit die 326 of the second integrated circuit structure 312. The film 324 may server a number of functions. For example, the film 324 may provide/insulation between the first integrated circuit structure 310 and the second integrated circuit structure 312. As another example, the film 324 may function as an adhesive material for attaching the first integrated circuit structure 310 and the second integrated circuit structure 3 12.

The second integrated circuit structure 312 preferably includes the second integrated circuit die 326 having a second insulating structure 328, such as an epoxy molding compound. A bottom surface of the second integrated circuit die 326 is preferably coupled to a top surface of the first insulating structure 316 of the first integrated circuit structure 310. The second integrated circuit die 326 has preferably second bond pads 330 electrically connected to the integrated circuits (not shown) within the second integrated circuit die 326.

The second insulating structure 328 preferably includes second conductive interconnects 332, such as solder bumps or gold bumps, bonded to the second bond pads 330, and a second recess 333 formed into the edges of the second insulating structure 328. The second insulating structure 328 at the second recess 333 preferably partially exposes the second conductive interconnects 332. Second interconnects 334, such as bond wires or ribbon bond wires, preferably couple the second conductive interconnects 332 to the carrier 302.

The first recess 321 and the second recess 333 may be preferably formed along multiple sides of the first integrated circuit structure 310 and the second integrated circuit structure 312. The first integrated circuit structure 310 and the second integrated circuit structure 312 may preferably be encapsulated in an encapsulation 338, such as an epoxy molding compound, covering the first interconnects 322 and the second interconnects 334 and forming the integrated circuit package system 300 with a low profile.

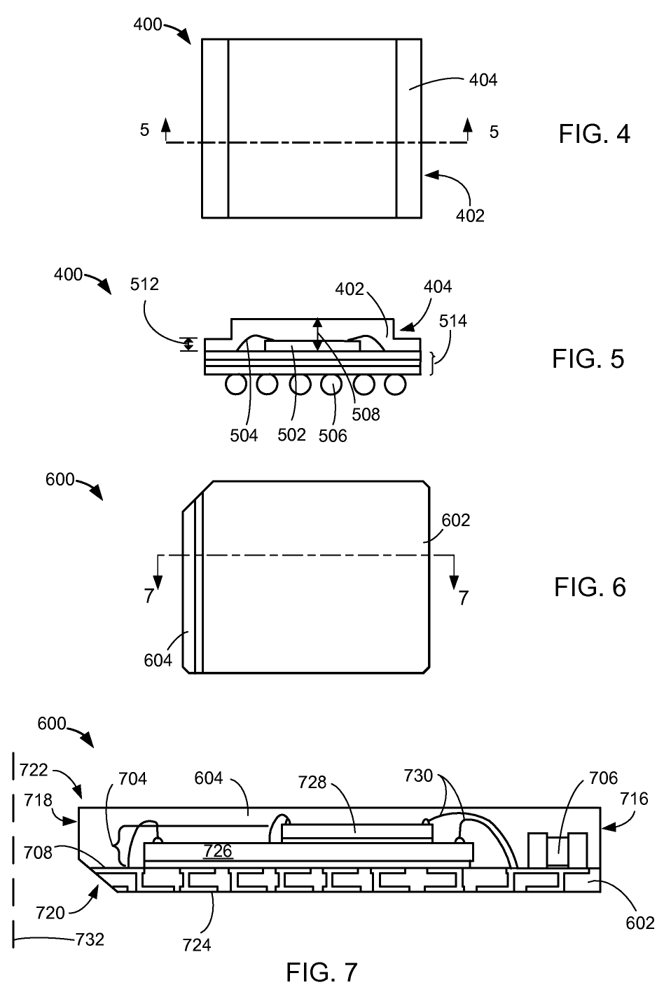

Referring now to FIG. 4, therein is shown a top view of an integrated circuit package system 400 in a third embodiment of the present invention. The top view depicts an encapsulation 402, such as an epoxy mold compound, preferably having a recess 404 at two opposing sides of the integrated circuit package system 400. For illustrative purposes, the integrated circuit package system 400 has the recess 404 in the encapsulation 402 at two opposing sides, although it is understood that the recess 404 may be formed in the encapsulation 402 at a different number of sides of the integrated circuit package system 400. For example, the integrated circuit package system 400 may have the recess 404 along all the sides of the integrated circuit package system 400.

Referring now to FIG. 5, therein is shown a cross-sectional view of the integrated circuit package system 400 along line 5-5 of FIG. 4. The cross-sectional view depicts an integrated circuit die 502 mounted over a carrier 514, such as a substrate. Internal interconnects 504, such as bond wires or ribbon bond wires, connect the integrated circuit die 502 and the carrier 514. The encapsulation 402 covers the integrated circuit die 502 and the internal interconnects 504 over the carrier 514. External interconnects 506, such as solder balls, attach to the carrier 514 at a side opposite the integrated circuit die 502.

For illustrative purposes, the integrated circuit die 502 is shown as a wire bonded integrated circuit, although it is understood that the integrated circuit die 502 may be a different type of integrated circuit. For example, the integrated circuit die 502 may be a flip chip, a packaged device, or stacked integrated circuits.

The encapsulation 402 preferably has a first thickness 508 at central region between the sides of the encapsulation 402 having the recess 404, wherein the first thickness 508 is the thickest portion of the encapsulation 402. The encapsulation 402 also preferably has a second thickness 512 at the recess 404.

The recess 404 in the encapsulation 402 eliminates some of the molding compound material from the encapsulation 402. The elimination of a portion of the encapsulation 402 reduces the size and weight of the integrated circuit package system 400. The recess 404 in the encapsulation 402 does not impede the internal interconnects 504 or the integrated circuit die 502.

Referring now to FIG. 6, therein is shown a bottom view of an integrated circuit package system 600 in a fourth embodiment of the present invention. The bottom view depicts a carrier 602, such as a laminate substrate, over an encapsulation 604, such as an epoxy molding compound.

Referring now to FIG. 7, therein is shown a cross-sectional view of the integrated circuit package system 600 along line 7-7 of FIG. 6. The integrated circuit package system 600 may preferably be a module, such as an expansion card or a pluggable card, used in an electronic system 732 depicted as a dotted line, such as hand held electronic appliance or an enterprise class server system. The integrated circuit package system 600 may provide a number of different functions or a combination of functions, such as providing connectivity for wireless access, additional storage, or identity information. The integrated circuit package system 600 preferably has the encapsulation 604 covering a first device 704, and a second device 706 with both connected to a first surface 708 of the carrier 602.

An insertion side 718 of the integrated circuit package system 600 preferably has a nonorthogonal lower segment 720 of the carrier 602 and the encapsulation 604. The insertion side 718 also preferably has an upper corner segment 722 of the encapsulation 604. The nonorthogonal lower segment 720 may preferably expose contacts (not shown) on a second surface 724 of the carrier 602. The contacts electrically connect the integrated circuit package system 600 and the electronic system 732. The nonorthogonal lower segment 720 may also help direct the integrated circuit package system 600 during insertion into, as well as mating with, the electronic system 732.

The first device 704 may be a stack of integrated circuits, such as a first integrated circuit die 726 below a second integrated circuit die 728, and connected to the carrier 602 with internal interconnects 730, such as bond wires. The second device 706 may be a passive component. The carrier 602 spans from approximate the insertion side 718 to an extraction side 716. The carrier 602 helps provide planar rigidity to the integrated circuit package system 600 as well as electrical connectivity.

For illustrative purpose, the first device 704 is shown as a stack of the first integrated circuit die 726 and the second integrated circuit die 728, although it is understood that the first device 704 may be a different configuration with different types, such as components or prepackaged devices. Also for illustrative purposes, the first integrated circuit die 726 and the second integrated circuit die 728 are shown as wire bonded to the carrier 602, although it is understood that the first integrated circuit die 726 and the second integrated circuit die 728 may be have different electrical connectivity, such as solder bumps for flip chip. Further for illustrative purposes, the second device 706 is shown as a passive component, although it is understood that the second device 706 may not be a passive component.

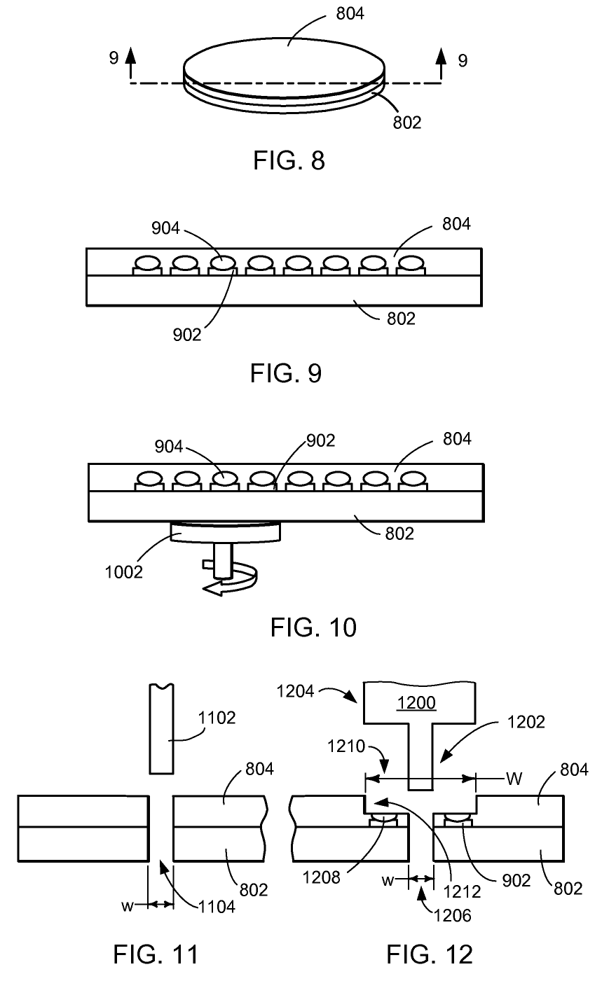

Referring now to FIG. 8, therein is shown a perspective view of a wafer 802 in a molding phase in accordance with an embodiment of the present invention. An insulating structure 804 is applied on the wafer 802. The insulating structure 804 may be formed on the wafer 802 in a different ways. For example, a material for the insulating structure 804 may be spun-on, poured within a rim barrier, injected in a mold, or otherwise applied. The insulating structure 804 may represent the first insulating structure 216 of FIG. 2, the second insulating structure 228 of FIG. 2, the first insulating structure 316 of FIG. 3, or the second insulating structure 328 of FIG. 3.

Referring now to FIG. 9, therein is shown a cross-sectional view of the wafer 802 along line 9-7 of FIG. 8. The cross-sectional view depicts the wafer 802 preferably with bond pads 902 coupled to active circuitry (not shown) fabricated within the wafer 802. The bond pads 902 may represent the first bond pads 218 of FIG. 2, the second bond pads 230 of FIG. 2, the first bond pads 318 of FIG. 3, or the second bond pads 330 of FIG. 3.

Conductive structures 904, such as conductive bumps comprised of solder, gold, or other metals or metal alloy, are formed on the bond pads 902. A covering material for the insulating structure 804 is applied over the wafer 802 covering the bond pads 902 and the conductive structures 904.

Referring now to FIG. 10, therein is the structure of FIG. 9 in a thinning phase. The backside of the wafer 802 undergoes a thinning process. The wafer 802 may be thinned in different ways. For example, a grinding wheel 1002 may traverse and thin the backside of the wafer 802 to a predetermined thickness. The bond pads 902, the conductive structures 904, and the insulating structure 804 are not affected by the thinning process.

Referring now to FIG. 11, therein is shown a portion of the structure FIG. 10 in a singulating phase along a parallel direction to 9-7 of FIG. 8. A dicing saw 1102 singulates through the insulating structure 804 and the wafer 802 forming a through cut 1104 having a width “w”.

Referring now to FIG. 12, therein is shown a portion of the structure FIG. 10 in the singulating phase. A multi-level saw 1200 includes a cutting portion 1202 and a stepped portion 1204. The multi-level saw 1200 singulates through the insulating structure 804 and the wafer 802 forming a through cut 1206 having a width “w”. The through cut 1206 is formed with the cutting portion 1202. In the same step forming the through cut 1206, the stepped portion 1204 of the multi-level saw 1200 partially cuts or partial grinds into the insulating structure 804 and grinding the conductive structures 904 of FIG. 10.

The stepped portion 1204 forms conductive interconnects 1208 and a stepped opening 1210 having a width “W” over the through cut 1206. The stepped opening 1210 may form the first recess 221 of FIG. 2, the second recess 233 of FIG. 2, the first recess 321 of FIG. 3, and the second recess 333 of FIG. 3. The conductive interconnects 1208 may represent the first conductive interconnects 220 of FIG. 2, the second conductive interconnects 232 of FIG. 2, the first conductive interconnects 320 of FIG. 3, and the second conductive interconnects 332 of FIG. 3. The stepped portion 1204 preferably does not remove the conductive interconnects 1208 and does not expose the bond pads 902.

The integrated circuit devices, such as the first integrated circuit structure 210 of FIG. 2 or the second integrated circuit structure 212 of FIG. 2, having been singulated by the multi-level saw 1200 have the characteristic of repeatable dimensions for a recess 1212 as a portion of the step opening 1210 in the insulating structure 804. Further, these integrated circuit devices having been singulated by the multi-level saw 1200 also have the characteristic of reduced damaged at the cut interfaces, such as the through cut 1206 and the stepped opening 1210. For example, the interface between the through cut 1206 and the stepped opening 1210 at the corner has less or no chipping, cracking, or ripping compared to conventional two-step cutting.

It has been discovered that the present invention improves manufacturing throughput and yield by singulating molded devices, such as molding compound covered wafers, with a multi-level saw having both a cutting portion and a stepped portion. The cutting portion provide side support as the stepped portion partially cuts or partially grinds the insulating structure and the conductive structures providing repeatable dimensions for the recess in the insulating structure. Also, the cutting portion provide side support as the stepped portion partially cuts or partially grinds the molding compound cover and the conductive structures eliminating or mitigating chipping, cracking, or tearing of the molding compound cover adjacent to the through cut. Inadvertent chipping, cracking, or tearing of the molding compound may expose the active circuitry (not shown) or the bond pads resulting in failed parts and reliability problems both leading to increased cost.

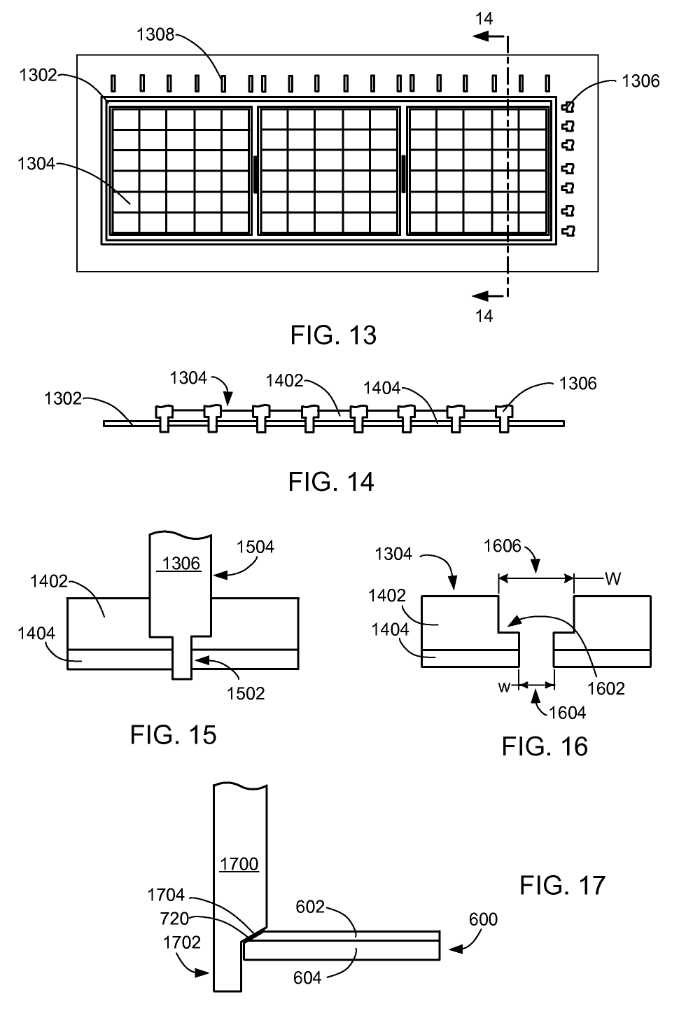

Referring now to FIG. 13, therein is shown a top view of a carrier frame 1302 in accordance with an embodiment of the present invention. The carrier frame 1302 includes a plurality of encapsulated devices 1304, such as integrated circuit package system with an encapsulation. The encapsulated devices 1304 may represent the integrated circuit package system 400 of FIG. 4.

The top view depicts a multi-level saw 1306 for cutting the encapsulated devices 1304 from the carrier frame 1302 in a first direction, such as along the x-axis, and to form recesses, such as the recess 404 of FIG. 4, in the encapsulated devices 1304. In this example, the multi-level saw 1306 cuts the carrier frame 1302 seven times.

The top view also depicts a cutting saw 1308 for cutting the encapsulated devices 1304 from the carrier frame 1302 in a second direction, such as along the y-axis. In this example, the cutting saw 1308 cuts the carrier frame 1302 eighteen times.

It has been discovered that the present invention improves manufacturing throughput and yield by singulating molded devices, such as molding compound covered wafers or packaged integrated circuits, with a multi-level saw having both a cutting portion and a stepped portion. The multi-level saw reduces singulation time and increases the throughput. In this example, the multi-level saw traverses the carrier frame seven times and the cutting saw traverses the carrier frame eighteen times extending the lifetime of the multi-level saw. The unit per hour (UPH) throughput improvement is approximately 36% compared to conventional two-step cut for forming the stepped contour in the encapsulated devices and for singulating the encapsulated devices from the carrier frame.

Referring now to FIG. 14, therein is shown a cross-sectional view of the carrier frame 1302 in a singulating phase along line 14-12 of FIG. 13. The cross-sectional view depicts the multi-level saw 1306 at the locations of cutting through the carrier frame 1302. The encapsulated devices 1304 includes an encapsulation 1402 having integrated circuit therein (not shown) over a carrier 1404, such as a substrate.

Referring now to FIG. 15, therein is shown a more detailed cross-sectional view of the structure of FIG. 14. The more detailed cross-sectional view depicts the multi-level saw 1306 having both a cutting portion 1502 and a stepped portion 1504. The cutting portion 1502 preferably cuts through the encapsulation 1402 and the carrier 1404. For illustrative purposes, the stepped portion 1504 of the multi-level saw 1306 does not cut the carrier 1404, although it is understood that the multi-level saw 1306 might cut from the carrier 1404 with the stepped portion 1504 cutting through the carrier 1404 and into the encapsulation 1402 without cutting through the encapsulation 1402.

Referring now to FIG. 16, therein is shown the structure of FIG. 15 post singulation. The encapsulated devices 1304 having both the encapsulation 1402 and the carrier 1404 are preferably singulated. The multi-level saw 1306 of FIG. 15 formed a recess 1602 in the encapsulation 1402. The multi-level saw 1306 formed a through cut 1604 having a width “w” and a stepped opening 1606 having a stepped opening “W”.

The integrated circuit devices, such as the integrated circuit package system 400 of FIG. 5, having been singulated by the multi-level saw 1306 have the characteristic of repeatable dimensions for the recess 1602 as a portion of the step opening 1606 in the encapsulation 1402. Further, these integrated circuit devices having been singulated by the multi-level saw 1306 also have the characteristic of reduced damaged at the cut interfaces, such as the through cut 1604 and the stepped opening 1606. For example, the interface between the through cut 1604 and the stepped opening 1606 at the corner has less or no chipping, cracking, or ripping compared to conventional two-step cutting.

It has been discovered that the present invention improves manufacturing throughput and yield by singulating molded devices, such as packaged integrated circuits, with a multi-level saw having both a cutting portion and a stepped portion. The cutting portion provide side support as the stepped portion partially cuts or partially grinds the encapsulation providing repeatable dimensions for the recess in the encapsulation. Also, the cutting portion provide side support as the stepped portion partially cuts or partially grinds the encapsulation eliminating or mitigating chipping, cracking, or tearing of the encapsulation adjacent to the through cut. Inadvertent chipping, cracking, or tearing of the encapsulation may expose the active circuitry (not shown), as an example, resulting in failed parts and reliability problems both leading to increased cost.

Referring now to FIG. 17, therein is shown a cross-sectional view of a portion the integrated circuit package system 600 of FIG. 7 in a singulating phase. The more detailed cross-sectional view depicts a multi-level saw 1700 having both a cutting portion 1702 and a sloped portion 1704. The cutting portion 1702 preferably cuts through the encapsulation 604 and the carrier 602. The sloped portion 1704 preferably forms the nonorthogonal lower segment 720 including a portion of the encapsulation 604 and a portion of the carrier 602.

The integrated circuit devices, such as the integrated circuit package system 600 of FIG. 7, having been singulated by the multi-level saw 1700 have the characteristic of repeatable dimensions for the nonorthogonal lower segment 702 of the carrier 602 and of the encapsulation 604. Further, these integrated circuit devices having been singulated by the multi-level saw 1700 also have the characteristic of reduced damaged at the cut interfaces, such as the vertical side and the nonorthogonal lower segment 720. For example, the interface between the vertical side and the nonorthogonal lower segment 720 has less or no chipping, cracking, or ripping compared to conventional two-step cutting.

It has been discovered that the present invention improves manufacturing throughput and yield by singulating molded devices, such as molding compound covered wafers or packaged integrated circuits, with a multi-level saw having both a cutting portion and a sloped portion. The cutting portion provide side support as the sloped portion partially cuts or partially grinds the encapsulation and the carrier eliminating or mitigating chipping, cracking, or tearing of the encapsulation adjacent to the through cut. Inadvertent chipping, cracking, or tearing of the encapsulation and the carrier may expose the active circuitry (not shown), as an example, resulting in failed parts and reliability problems both leading to increased cost. Also, the unit per hour (UPH) throughput improvement is approximately 46% compared to conventional two cut step for forming the sloped contour in the encapsulated devices and for singulating three rows of encapsulated devices from a carrier frame. The decrease cutting runs by the multi-level saw extends its lifetime.

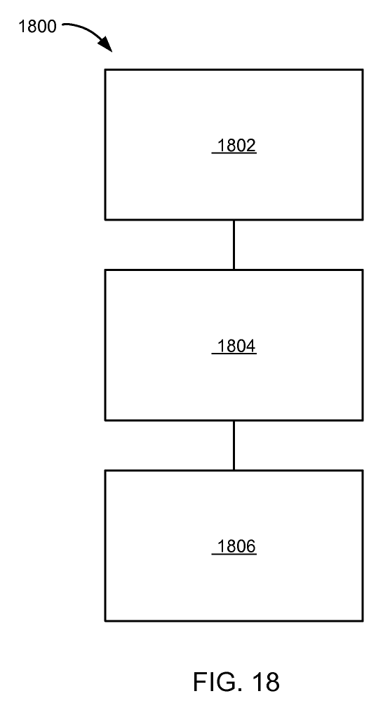

Referring now to FIG. 18, therein is shown a flow chart of an integrated circuit package system 1800 for manufacturing the integrated circuit package system 100 in an embodiment of the present invention. The system 1800 includes providing an integrated circuit die in a block 1802; forming an encapsulation over the integrated circuit die in a block 1804; and sawing the encapsulation with a multi-level saw in a block 1806.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit package system of the present invention furnishes important and heretofore unknown and unavailable solutions, capabilities, and functional aspects for improving yield, increasing reliability, and reducing cost of integrated circuit package system. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package system comprising:
providing an integrated circuit die;
forming an encapsulation over the integrated circuit die; and
sawing the encapsulation with a multi-level saw.

2. The system as claimed in claim 1 wherein sawing the encapsulation includes forming a recess at a vertical side of the encapsulation.

3. The system as claimed in claim 1 wherein sawing the encapsulation includes forming a sloped portion at a vertical side of the encapsulation.

4. The system as claimed in claim 1 further comprising connecting a carrier and the integrated circuit die.

5. The system as claimed in claim 1 further comprising providing the multi-level saw having a cutting portion and a stepped portion or a sloped portion.

6. An integrated circuit package system comprising:
providing an integrated circuit die;
forming an encapsulation over the integrated circuit die;
sawing the encapsulation with a dicing saw in a first direction; and
sawing the encapsulation with a multi-level saw in a second direction intersecting the first direction.

7. The system as claimed in claim 6 wherein:
providing the integrated circuit die includes:
providing a conductive structure over the integrated circuit die; forming the encapsulation includes:
covering the conductive structure with the encapsulation; and sawing the encapsulation includes:
forming a conductive interconnect by grinding the conductive structure and the encapsulation with the multi-level saw.

8. The system as claimed in claim 6 wherein:
providing the integrated circuit die includes:
providing a conductive structure over the integrated circuit die; forming the encapsulation includes:
covering the conductive structure with the encapsulation; sawing the encapsulation includes:
forming a conductive interconnect by grinding the conductive structure and the encapsulation with the multi-level saw;
further comprising:
connecting a carrier and the conductive interconnect; and
forming a package mold over the encapsulation and the conductive interconnect.

9. The system as claimed in claim 6 further comprising:
mounting the integrated circuit die over a carrier;
connecting the integrated circuit die and the carrier;
wherein:
forming the encapsulation includes:
covering the integrated circuit die over the carrier; and
sawing the encapsulation includes:
forming a recess in the encapsulation.

10. The system as claimed in claim 6 further comprising:
mounting the integrated circuit die over a carrier;
connecting the integrated circuit die and the carrier;
wherein:
forming the encapsulation includes:
covering the integrated circuit die over the carrier;
sawing the encapsulation includes:
forming a nonorthogonal segment in the encapsulation; and
forming the nonorthogonal segment in the carrier.

11. An integrated circuit package system comprising:
an integrated circuit die; and
an encapsulation over the integrated circuit die with the encapsulation having a multi-level side characteristic of being sawed by a multi-level saw.

12. The system as claimed in claim 11 wherein the encapsulation includes a recess at a vertical side of the encapsulation.

13. The system as claimed in claim 11 wherein the encapsulation includes a sloped portion at a vertical side of the encapsulation.

14. The system as claimed in claim 11 further comprising a carrier connected with the integrated circuit die.

15. The system as claimed in claim 11 further comprising the multi-level saw having a cutting portion and a stepped portion or a sloped portion.

16. The system as claimed in claim 11 wherein the encapsulation has a vertical portion of the multi-level side.

17. The system as claimed in claim 16 wherein:
the integrated circuit die includes a conductive interconnect; and
the encapsulation exposes the conductive interconnect.

18. The system as claimed in claim 16 wherein:
the integrated circuit die includes a conductive interconnect;
the encapsulation exposes the conductive interconnect;
further comprising:
a carrier connected with the conductive interconnect; and
a package mold over the encapsulation and the conductive interconnect.

19. The system as claimed in claim 16 further comprising:
the integrated circuit die over and connected to a carrier; and
wherein:
the encapsulation has a recess and is over the carrier.

20. The system as claimed in claim 16 further comprising:
the integrated circuit die over and connected to a carrier; and
wherein:
the encapsulation has a nonorthogonal segment and is over the carrier; and
the carrier has the nonorthogonal segment.
